(19) United States
(12) Patent Application Publication
(10) Pub. No.: US 2026/0136912 A1
(43) Pub. Date: May 14, 2026

(54) SEMICONDUCTOR DEVICES HAVING NON-CONTINUOUS METAL GATE RUNNERS

(71) Applicant: Wolfspeed, Inc., Durham, NC (US)

(72) Inventors: Daniel Richter, Raleigh, NC (US); Adam Barkley, Chapel Hill, NC (US); Michael Maas, Apex, NC (US)

(21) Appl. No.: 18/942,905

(22) Filed: Nov. 11, 2024

(51) Int. Cl. H01L 23/528; H01L 23/532; H01L 27/088; H01L 29/16; H01L 29/417; H01L 29/78

(52) U.S. Cl. CPC H10W 20/427; H10D 64/252; H10W 20/4451; H10D 30/66; H10D 62/8325; H10D 84/83

(57) ABSTRACT

A semiconductor device comprises a semiconductor layer structure that comprises at least one wide bandgap semiconductor layer; a gate pad on the semiconductor layer structure; and a gate runner that is electrically connected to the gate pad, the gate runner comprising a polysilicon gate runner and a metal gate runner on the polysilicon gate runner opposite the semiconductor layer structure. A gap is provided in the metal gate runner above a first portion of the polysilicon gate runner, where the gap separates the metal gate runner into a first metal gate runner segment and a second metal gate runner segment or separates the first metal gate runner segment from the gate pad.

### FIELD

The present invention relates to semiconductor devices and, more particularly, to gate-controlled power semiconductor devices and to methods of fabricating such devices.

### BACKGROUND

The Metal Oxide Semiconductor Field Effect Transistor (“MOSFET”) is a well-known type of semiconductor transistor that may be used as a switch. A MOSFET is a three terminal device that has gate, drain and source terminals and a semiconductor body. The semiconductor body is referred to herein as a “semiconductor layer structure” and may include one or more semiconductor layers/regions. A source region and a drain region that each have a first conductivity type are formed in the semiconductor layer structure and are separated from each other by a channel region that has a second conductivity type. A gate electrode is disposed adjacent the channel region and separated from the channel region by a thin oxide layer. A MOSFET may be turned on or off by setting a bias voltage that is applied to the gate electrode to be above or below a threshold value. When a MOSFET is turned on (i.e., it is in its “on-state”), current is conducted through the channel region between the source and drain regions. When the bias voltage is reduced below the threshold level, the current ceases to conduct through the channel region.

An n-type MOSFET has source and drain regions that have n-type (electron) conductivity and a channel region that has p-type (hole) conductivity (i.e., an “n-p-n” design). An n-type MOSFET turns on when a gate bias voltage is applied to the gate electrode that is sufficient to create a conductive n-type inversion layer in the p-type channel region, thereby electrically connecting the n-type source and drain regions and allowing for majority carrier conduction therebetween. A p-type MOSFET has a “p-n-p” design (i.e., p-type source and drain regions and an n-type channel region) and turns on when a gate bias voltage is applied to the gate electrode that is sufficient to create a conductive p-type inversion layer in the n-type channel region to electrically connect the p-type source and drain regions. Herein, the terms “first conductivity type” and “second conductivity type” are used to indicate either n-type or p-type conductivity, where the first and second conductivity types are different. Thus, if a first region of a device has a first conductivity type and a second region of the device has a second conductivity type, this means either that the first region has n-type conductivity and the second region has p-type conductivity or, alternatively, that first region has p-type conductivity and the second region has n-type conductivity.

Because the gate electrode of a MOSFET is insulated from the channel region by the gate oxide layer, minimal gate current is required to maintain the MOSFET in its on-state or to switch the MOSFET between its off-state and its on-state. The gate current is kept small during switching because the gate forms a capacitor with the channel region. Thus, only minimal charging and discharging current is required during switching, allowing for less complex gate drive circuitry and faster switching speeds. MOSFETs may be stand-alone devices or may be combined with other circuit devices. For example, an Insulated Gate Bipolar Transistor (“IGBT”) is a semiconductor device that includes both a MOSFET and a Bipolar Junction Transistor (“BJT”) that combines the high impedance gate electrode of the MOSFET with the small on-state conduction losses that may be provided by a BJT.

In many applications, MOSFETs may need to carry large currents and/or be capable of blocking high voltages (e.g., hundreds or thousands of volts of electric potential). Such MOSFETs are often referred to as “power” MOSFETs. Power MOSFETs are often fabricated from wide band-gap semiconductor materials (herein, the term “wide band-gap semiconductor” encompasses any semiconductor having a band-gap of at least 1.4 eV). Power MOSFETs and other power semiconductor devices are often formed in silicon carbide (“SiC”), which has a number of advantageous characteristics including, for example, a high electric field breakdown strength, high thermal conductivity, high electron mobility, high melting point and high-saturated electron drift velocity.

Power semiconductor devices such as power MOSFETs can have a lateral structure or a vertical structure. In a device having a lateral structure, the terminals of the device (e.g., the drain, gate and source terminals for a power MOSFET) are on the same major surface (i.e., top or bottom) of a semiconductor layer structure. In contrast, in a device having a vertical structure, at least one terminal is provided on each major surface of the semiconductor layer structure (e.g., in a vertical MOSFET, the source and gate may be on the top surface of the semiconductor layer structure and the drain may be on the bottom surface of the semiconductor layer structure).

The semiconductor layer structure of a power semiconductor device includes an “active region” which acts as a main junction for blocking voltage during reverse bias (off-state) operation and for providing current flow during forward bias (on-state) operation. The power semiconductor device may also have an edge termination structure such as guard rings or a junction termination extension in a termination region of the semiconductor layer structure that is adjacent (and typically surrounding) the active region. The edge termination structure may, among other things, reduce electric field crowding effects that can occur at the outer edges of a power semiconductor device. Typically, multiple power semiconductor devices are formed in/on a common wafer, and each power semiconductor device will typically have its own edge termination structure. After the wafer is fully processed, the resultant structure may be diced to separate the individual edge-terminated power semiconductor devices. The singulated pieces of the wafer are often referred to as individual semiconductor die. Each power semiconductor device may have a unit cell structure in which the active region of each power semiconductor device includes a plurality of individual “unit cell” devices that are electrically connected in parallel and that together function as a single power semiconductor device.

Vertical gate-controlled power semiconductor devices can have a planar gate electrode design in which the gate electrodes are formed on top of the semiconductor layer structure or, alternatively, may have the gate electrodes formed within gate trenches in the semiconductor layer structure, which are typically referred to as gate trench devices. With the planar gate electrode design, the channel region of each unit cell transistor is horizontally disposed underneath the gate electrode. In contrast, in gate trench devices, the channels are typically vertically disposed adjacent sidewalls of the gate electrodes. Gate trench devices may provide enhanced performance, but typically require a more complicated manufacturing process. It will be appreciated that the metal gate runner designs of the semiconductor devices according to embodiments of the present invention that are discussed herein can be implemented in semiconductor devices having either planar or gate trench gate electrode designs.

FIGS. 1A-1C illustrate a conventional vertical silicon carbide based power MOSFET 1. In particular, FIG. 1A is a schematic top view of power MOSFET 1, FIG. 1B is a schematic plan (i.e., top) view of power MOSFET 1 with various of the upper metal and dielectric layers omitted so that the gate structure is visible, and FIG. 1C is a cross-sectional view taken along line 1C-1C of FIG. 1B. Power MOSFET 1 includes a semiconductor layer structure 20 that comprises one or more semiconductor substrates and/or layers, where at least one of the semiconductor layers is a silicon carbide layer. Various metal and/or dielectric layers are formed on either side of the semiconductor layer structure 20 and gate electrodes for the unit cell transistors may be provided on and/or embedded in the semiconductor layer structure 20.

Referring to FIG. 1A, the top-side metal layers include a gate pad 2 and a plurality of source pads 4-1 through 4-4 that are formed on the upper side of the semiconductor layer structure 20. A drain pad 6 (FIG. 1C) is provided on the bottom side of the semiconductor layer structure 20. The gate pad 2, the source pads 4 and the drain pad 67 form the respective gate, source and drain terminals of power MOSFET 1. The gate and source pads 2, 4 may each be formed of a metal, such as aluminum. The drain pad 6 may likewise be a metal pad. A protective layer 8 such as a polyimide layer may cover the entire upper surface of power MOSFET 1 except for the gate and source pads 2, 4.

Still referring to FIG. 1A, power MOSFET 1 also includes a source metallization 70 that electrically connects certain regions of the semiconductor layer structure 20 to the source bond pads 4-1 through 4-4. The source metallization 70 is formed within the region indicated by the dashed box labelled 70 in FIG. 1A. The source bond pads 4-1 through 4-4 typically are simply portions of the source metallization 70 that are exposed through openings in the protective layer 8. The source metallization 70 may generally overlie or correspond to an “active region” 7 of the power MOSFET 1 where the unit cell transistors are located that conduct current during on-state operation and block voltages during reverse bias (off-state) operation. Power MOSFET 1 also includes an inactive region 9. The inactive region 9 may include a termination region 9A that at least partially surrounds the active region 7, a gate pad region that underlies the gate pad 2, and gate bus regions (discussed below). The termination region 9A is designed to reduce electric field crowding effects that can occur at the periphery of the active region 7. The termination region 9A may include one or more termination structures (not shown) such as guard rings or a junction termination extension.

Bond wires 3 are shown in FIG. 1A that may be used to connect the gate pad 2 and the source pads 4 to external circuits or the like. The drain pad 6 on the bottom side of power MOSFET 1 may be connected to an external circuit through, for example, an underlying submount (not shown).

In FIG. 1B the polyimide layer 8 the source metallization 70 and an intermetal dielectric layer are omitted to illustrate the gate structure of power MOSFET 1. As shown in FIG. 1B, the gate structure comprises the metal gate pad 2, a gate runner 10 that is electrically connected to the gate pad 20, and a plurality of gate electrodes 50. The gate runner 10 includes a polysilicon gate runner 12 (FIG. 1C) and a metal gate runner 16. The polysilicon gate runner 12 is formed between the semiconductor layer structure 20 and the metal gate runner 16.

As is known in the art, gate runners such as gate runner 10 may extend around the periphery of the active region 7 and/or may extend into the active region 7. Herein, the term “outer” gate runner is used to refer to a gate runner or a portion thereof that extends around a periphery of the active region (e.g., positioned between the active region and the termination region) so that the active region is on only one side of the gate runner. In contrast, herein the term “inner” gate runner is used to refer to a gate runner or a portion thereof that are within a region defined by an outer periphery or “footprint” of the active region. Thus, an inner gate runner refers to the portions of a gate runner that extend into the footprint of the active region so that the active region is on two opposed sides of each portion of an inner gate runner. An inner gate runner is not part of the active region, but extends into the active region.

As can be seen from FIG. 1B, the gate runner 10 of power MOSFET 1 only includes an inner gate runner. The metal gate runner 16 may vertically overlap the polysilicon gate runner 12 and may have an identical or almost identical footprint as compared to the polysilicon gate runner 12. The metal gate runner 16 includes eight distinct segments 18, namely a first metal gate runner segment 18-1 that extends to the left from the upper left corner of the gate pad 2, a second metal gate runner segment 18-2 that extends to the right from the upper right corner of the gate pad 2, a third metal gate runner segment 18-3 that extends from the lower center of the gate pad 2, a sixth metal gate runner segment 18-6 that extends from a distal end of the third metal gate runner segment 18-3, a fourth metal gate runner segment 18-4 that extends to the left from the intersection of the third and sixth metal gate runner segments 18-3, 18-6, a fifth metal gate runner segment 18-4 that extends to the right from the intersection of the third and sixth metal gate runner segments 18-3, 18-6, a seventh metal gate runner segment 18-7 that extends to the left from the distal end of the sixth metal gate runner segment 18-6, and an eighth metal gate runner segment 18-8 that extends to the right from the distal end of the sixth metal gate runner segment 18-6. The third through eighth metal gate runner segments 18-3 through 18-8 have a spine and rib configuration in which a spine (namely the third and sixth metal gate runner segments 18-3, 18-6) extends from the gate pad 2 and a plurality of ribs (namely the third and fifth and seventh and eighth metal gate runner segments 18-4, 18-5, 18-7, 18-8) extend from each side of the spine.

Power MOSFET 1 further includes a plurality of gate electrodes 50 that extend from the gate runner 10 and/or from the gate pad 2. The region where the gate electrodes 50 are provided corresponds to the active region 7. Thin gate dielectric layers 52 separate each gate electrode 50 from the semiconductor layer structure 20. Both horizontally-extending (i.e., in the x-direction) and vertically extending (i.e., in the y-direction) gate electrodes 50 are provided. When a gate signal is input to the gate pad 2, the gate signal primarily flows to the gate runner 10, and from the gate runner 10 to the gate electrodes 50. However, some portions of the gate signal will flow directly from the gate pad 2 to the gate electrodes 50 that are directly connected to the gate pad 2, and may then flow through portions of the gate electrode mesh.

FIG. 1C is a schematic cross-sectional view taken along line 1C-1C of FIG. 1B. The upper dielectric and metal layers that are omitted in FIG. 1B are added in FIG. 1C for context.

As shown in FIG. 1C, power MOSFET 1 includes an n-type silicon carbide substrate 22. The drain contact 6 is formed on the lower surface of the substrate 22. A lightly-doped n-type silicon carbide drift region 24 is provided on the upper surface of the substrate 22. A heavily-doped p-type region 30 is formed in an upper portion of the n-type drift region 24, and a field oxide layer 58 is formed on the heavily-doped p-type region 30. Thinner gate oxide layers 52 are formed on the upper surface of the semiconductor layer structure 20 on either side of the field oxide layer 58.

A polysilicon gate runner 12 is formed on the field oxide layer 58, and gate electrodes 50 are formed on the gate oxide layers 52. Opposed sides of the polysilicon gate runner 12 merge into the gate electrodes 50 so that the polysilicon gate runner 12 is physically and electrically connected to the gate electrodes 50. An intermetal dielectric layer 54 may cover the respective gate electrodes 150. The intermetal dielectric layers 154 covers the gate electrodes 50 and portions of the polysilicon gate runner 12. A longitudinally-extending via 56 is provided in the intermetal dielectric layer 54 that exposes the upper surface of a central portion of the polysilicon gate runner 12. A metal gate runner 16 is formed on the intermetal dielectric layer 54 and also fills the longitudinally-extending via 56 so that the metal gate runner 16 physically and electrically contacts the polysilicon gate runner 12. The outer gate runner 16 vertically overlaps the polysilicon runner 12.

The gate electrodes 50 in conventional silicon carbide based power MOSFETs are typically formed of polysilicon. Since the resistance of polysilicon is orders of magnitude greater than the resistance of a metal such as aluminum, the gate signals pass along the gate electrodes 50 relatively slowly, which negatively impacts the switching speed of power MOSFET 1. The metal gate runner 16 provides a low-resistance path between the metal gate pad 2 and the gate electrodes 50, which improves the switching performance. The gate signals will almost entirely flow along the metal gate runner 16 (since metal is much less resistive than polysilicon) as the signal passes from the gate pad 2 to the gate electrodes 50. Note that herein the term “metal gate runner” encompasses both metal gate runners and metal silicide gate runners.

### SUMMARY

Pursuant to embodiments of the present invention, semiconductor devices are provided that comprise a semiconductor layer structure that comprises at least one wide bandgap semiconductor layer, a gate pad on the semiconductor layer structure, and a gate runner that is electrically connected to the gate pad, the gate runner comprising a polysilicon gate runner and a metal gate runner on the polysilicon gate runner opposite the semiconductor layer structure. A gap is provided in the metal gate runner above a first portion of the polysilicon gate runner, where the gap separates the metal gate runner into a first metal gate runner segment and a second metal gate runner segment or separates the first metal gate runner segment from the gate pad.

In some embodiments, the gap separates the metal gate runner into the first and second metal gate runner segments, and wherein the first portion of the polysilicon gate runner electrically connects the first metal gate runner segment to the second metal gate runner segment.

In some embodiments, the semiconductor device further comprises a source metallization on the semiconductor layer structure, wherein a portion of the source metallization extends above and vertically overlaps the gap. In such embodiments, the semiconductor device may further include a source bond wire that is electrically connected to the source metallization and is on a first side of the gap when the semiconductor device is viewed from above and a unit cell transistor that is on a second side of the gap when the semiconductor device is viewed from above, the second side of the gap opposite the first side of the gap. A primary current path from the unit cell transistor to the source bond wire is through the portion of the source metallization that extends above and vertically overlaps the gap.

In some embodiments, the source metallization includes a first opening when the semiconductor device is viewed from above, and the first metal gate runner segment is within the first opening in the source metallization and surrounded by the source metallization. In some embodiments, second metal gate runner segment is not within the first opening in the source metallization.

In some embodiments, the gap is a first gap, and wherein the metal gate runner is separated from the gate pad by a second gap, and the polysilicon gate runner is provided beneath the second gap, and the source metallization extends above and vertically overlaps the second gap.

In some embodiments, a first distance between the first and second metal gate runner segments across the gap is less than 10% a length of a longest side of the semiconductor layer structure. In other embodiments, the first distance may be less than 5% the length of the longest side of the semiconductor layer structure.

In some embodiments, the first metal gate runner segment is collinear with the second metal gate runner segment. In other embodiments, the first metal gate runner segment extends along a first longitudinal axis and the second metal gate runner segment extends along a second longitudinal axis that is perpendicular to the first longitudinal axis.

In some embodiments, the first metal gate runner segment and the second metal gate runner segment are each part of an inner gate runner. In some embodiments, the inner gate runner comprises a spine and rib configuration that comprises a spine and a plurality of ribs, wherein the gap is in between the spine and a first of the ribs.

In some embodiments, the gap separates the first metal gate runner segment from the gate pad, and wherein the first portion of the polysilicon gate runner electrically connects the first metal gate runner segment to the gate pad. In some embodiments, the semiconductor device further comprises a source metallization on the semiconductor layer structure, where a portion of the source metallization extends above and vertically overlaps the gap. The semiconductor device may further comprise a source bond wire that is electrically connected to the source metallization and is on a first side of the gap when the semiconductor device is viewed from above and a unit cell transistor that is on a second side of the gap when the semiconductor device is viewed from above, the second side of the gap opposite the first side of the gap. A primary current path from the unit cell transistor to the source bond wire is through the portion of the source metallization that extends above and vertically overlaps the gap.

In some embodiments, the source metallization includes a first opening when the semiconductor device is viewed from above, and the first metal gate runner segment is within the first opening in the source metallization and surrounded by the source metallization. In some embodiments, the metal gate runner includes a second metal gate runner segment that is not within the first opening in the source metallization.

In some embodiments, the semiconductor device comprises a metal oxide semiconductor field effect transistor that comprises a plurality of unit cell transistors.

Pursuant to still other embodiments of the present invention, semiconductor devices are provided that comprise a semiconductor layer structure that comprises at least one wide bandgap semiconductor layer, a gate pad on the semiconductor layer structure, and a metal gate runner on the semiconductor layer structure that comprises first and second metal gate runner segments that are spaced-apart from each other by a gap. A primary electrical connection between the second metal gate runner segment and the gate pad is through the first metal gate runner segment.

In some embodiments, the semiconductor device may further comprise a source metallization on the semiconductor layer structure that is above and vertically overlaps the gap. In some embodiments, the metal gate runner is part of a gate runner that is electrically connected to the gate pad, the gate runner further comprising a polysilicon gate runner that is in between the metal gate runner and the semiconductor layer structure. In some embodiments, a first portion of the polysilicon gate runner extends underneath the gap. In some embodiments, the first portion of the polysilicon gate runner electrically connects the first metal gate runner segment to the second metal gate runner segment.

In some embodiments, the semiconductor device further comprises a source bond wire that is electrically connected to the source metallization and is on a first side of the gap when the semiconductor device is viewed from above and a unit cell transistor that is on a second side of the gap that is opposite the first side of the gap when the semiconductor device is viewed from above. A primary current path from the unit cell transistor to the source bond wire is through a portion of the source metallization that extends above and vertically overlaps the gap.

In some embodiments, a first distance between the first and second metal gate runner segments across the gap is less than 10% a length of a longest side of the semiconductor layer structure.

In some embodiments, the source metallization includes a first opening when the semiconductor device is viewed from above and the first metal gate runner segment is within the first opening in the source metallization and surrounded by the source metallization. In some embodiments, the second metal gate runner segment is not within the first opening in the source metallization.

In some embodiments, the first metal gate runner segment is collinear with the second metal gate runner segment.

In some embodiments, the first metal gate runner segment extends along a first longitudinal axis and the second metal gate runner segment extends along a second longitudinal axis that is perpendicular to the first longitudinal axis.

In some embodiments, the gap is a first gap, and wherein the metal gate runner is separated from the gate pad by a second gap, and a polysilicon gate runner is provided beneath the second gap, and the source metallization extends above and vertically overlaps the second gap.

In some embodiments, the gate runner comprises a spine and rib configuration that comprises a spine and a plurality of ribs, wherein the gap is in between the spine and a first of the ribs.

Pursuant to additional embodiments of the present invention, semiconductor devices are provided that comprise a semiconductor layer structure that comprises at least one wide bandgap semiconductor layer, a gate pad on the semiconductor layer structure, a metal gate runner on the semiconductor layer structure that comprises a metal gate runner segment that is spaced-apart from the gate pad by a gap, and a polysilicon structure on the semiconductor layer structure that electrically connects the gate pad to the metal gate runner segment.

In some embodiments, at least a portion of the gate pad vertically overlaps a part of the polysilicon structure.

In some embodiments, the metal gate runner is part of a gate runner that is electrically connected to the gate pad and the polysilicon structure comprises a polysilicon gate runner that is also part of the gate runner, where the polysilicon gate runner that is in between the metal gate runner and the semiconductor layer structure.

In some embodiments, a first distance between the metal gate runner segment and the gate pad across the gap is less than 10% a length of a longest side of the semiconductor layer structure.

In some embodiments, the semiconductor device further comprises a source metallization on the semiconductor layer structure, wherein a first portion of the source metallization extends above and vertically overlaps the gap.

In some embodiments, the semiconductor device further comprises a source bond wire that is electrically connected to the source metallization and is on a first side of the gap when the semiconductor device is viewed from above and a unit cell transistor that is on a second side of the gap that is opposite the first side of the gap when the semiconductor device is viewed from above. A primary current path from the unit cell transistor to the source bond wire is through the first portion of the source metallization.

In some embodiments, the source metallization includes a first opening when the semiconductor device is viewed from above and the metal gate runner segment is within the first opening in the source metallization and surrounded by the source metallization.

Pursuant to further embodiments of the present invention, semiconductor devices are provided that comprise a semiconductor layer structure that comprises at least one wide bandgap semiconductor layer, a gate pad on the semiconductor layer structure, a source metallization on the semiconductor layer structure, and a metal gate runner on the semiconductor layer structure that comprises at least first and second metal gate runner segments. The source metallization comprises a first opening when the semiconductor device is viewed from above, and the first metal gate runner segment is within the opening and the second metal gate runner segment is outside the opening when the semiconductor device is viewed from above.

In some embodiments, the metal gate runner is part of a gate runner that is electrically connected to the gate pad, the gate runner further comprising a polysilicon gate runner that is in between the metal gate runner and the semiconductor layer structure. In some embodiments, the first and second metal gate runner segments are separated from each other by a gap, and a first portion of the polysilicon gate runner extends underneath the gap. In some embodiments, the first portion of the polysilicon gate runner electrically connects the first metal gate runner segment to the second metal gate runner segment.

In some embodiments, the semiconductor device further comprises a source bond wire that is electrically connected to the source metallization and is on a first side of the gap when the semiconductor device is viewed from above and a unit cell transistor that is on a second side of the gap that is opposite the first side of the gap. A primary current path from the unit cell transistor to the source bond wire is through a portion of the source metallization that extends above and vertically overlaps the gap.

In some embodiments, the first metal gate runner segment is collinear with the second metal gate runner segment.

In some embodiments, the first metal gate runner segment extends along a first longitudinal axis and the second metal gate runner segment extends along a second longitudinal axis that is perpendicular to the first longitudinal axis.

In some embodiments, the gap is a first gap, and wherein the metal gate runner is separated from the gate pad by a second gap, and a polysilicon gate runner is provided beneath the second gap, and the source metallization extends above the second gap.

In some embodiments, the gate runner comprises a spine and rib configuration that comprises a spine and a first rib, and the gap is in between the spine and the first rib.

In some embodiments, the first metal gate runner segment and the gate pad are separated from each other by a gap, and a first portion of the polysilicon gate runner extends underneath the gap.

In some embodiments, the first portion of the polysilicon gate runner electrically connects the first metal gate runner segment to the gate pad.

Pursuant to still further embodiments of the present invention, semiconductor devices are provided that comprise a semiconductor layer structure that comprises at least one wide bandgap semiconductor layer, a gate pad on the semiconductor layer structure, and a metal gate runner on the semiconductor layer structure that comprises an inner metal gate runner that has a spine that has a first end that is electrically connected to the gate pad and a plurality of ribs that extend perpendicularly from the spine. A first of the ribs is separated from the spine by a gap and electrically connected to the spine by a conductive structure underlying the gap.

In some embodiments, the metal gate runner is part of a gate runner that is electrically connected to the gate pad, the gate runner further comprising a polysilicon gate runner that is in between the metal gate runner and the semiconductor layer structure.

In some embodiments, a first portion of the polysilicon gate runner extends underneath the gap.

In some embodiments, the first portion of the polysilicon gate runner electrically connects the first of the ribs to the spine.

In some embodiments, the semiconductor device further comprises a source metallization on the semiconductor layer structure, wherein a portion of the source metallization extends above and vertically overlaps the gap.

In some embodiments, the semiconductor device further comprises a source bond wire that is electrically connected to the source metallization and is on a first side of the gap when the semiconductor device is viewed from above and a unit cell transistor that is on a second side of the gap that is opposite the first side of the gap. A primary current path from the unit cell transistor to the source bond wire is through a portion of the source metallization that extends above and vertically overlaps the gap.

In some embodiments, the source metallization includes a first opening when the semiconductor device is viewed from above, and the first of the ribs is within the first opening in the source metallization and surrounded by the source metallization. In some embodiments, the spine is outside the first opening in the source metallization.

In some embodiments, conductive structure comprises a gate electrode of a unit cell transistor.

Pursuant to other embodiments of the present invention, semiconductor devices are provided that comprise a semiconductor layer structure that comprises at least one wide bandgap semiconductor layer, a gate pad on the semiconductor layer structure, a plurality of unit cell transistors on the semiconductor layer structure, each unit cell transistor including a respective polysilicon gate electrode, and a metal gate runner on the semiconductor layer structure that comprises first and second metal gate runner segments that are separated from each other by a gap. A primary electrical connection between the second metal gate runner segment and the gate pad is through one or more of the polysilicon gate electrodes.

In some embodiments, the metal gate runner is part of a gate runner that is electrically connected to the gate pad, the gate runner further comprising a polysilicon gate runner that is in between the metal gate runner and the semiconductor layer structure. In some embodiments, the polysilicon gate runner is a first part of a polysilicon pattern and the plurality of polysilicon gate electrodes are a second part of the polysilicon pattern.

In some embodiments, the source metallization includes a first opening when the semiconductor device is viewed from above, and the first metal gate runner segment is within the first opening in the source metallization opening and surrounded by the source metallization. In some embodiments, the second metal gate runner segment is not within the first opening in the source metallization.

Pursuant to yet additional embodiments of the present invention, semiconductor devices are provided that comprise a semiconductor layer structure that comprises at least one wide bandgap semiconductor layer and a metal gate structure on the semiconductor layer structure, the gate structure comprising a metal gate pad and a metal gate runner. A first gap is provided in the metal gate structure where metal is omitted so that a first portion of the metal gate structure is spaced apart from a second portion of the metal gate structure by the first gap, where the first portion of the metal gate structure is electrically connected to the second portion of the metal gate structure via a conductive structure that is below the first gap.

In some embodiments, the first portion of the metal gate structure is a first metal gate runner segment of the metal gate runner and the second portion of the metal gate structure is the metal gate pad.

In some embodiments, the conductive structure is a polysilicon gate runner.

In some embodiments, the conductive structure is a polysilicon gate electrode.

In some embodiments, the first portion of the metal gate structure is a first metal gate runner segment of the metal gate runner and the second portion of the metal gate structure is a second metal gate runner segment of the metal gate runner. In some embodiments, the first and second metal gate runner segments are collinear. In some embodiments, the second metal gate runner segment does not physically connect to the metal gate pad.

In some embodiments, the polysilicon gate runner is in between the metal gate runner and the semiconductor layer structure.

In some embodiments, the semiconductor device further comprises a source metallization on the semiconductor layer structure, wherein a first portion of the source metallization extends above and vertically overlaps the first gap.

In some embodiments, the semiconductor device further comprises a source bond wire that is electrically connected to the source metallization and is on a first side of the first gap when the semiconductor device is viewed from above and a unit cell transistor that is on a second side of the first gap that is opposite the first side of the first gap when the semiconductor device is viewed from above. A primary current path from the unit cell transistor to the source bond wire is through a portion of the source metallization that extends above and vertically overlaps the first gap.

### BRIEF DESCRIPTION OF DRAWINGS

FIG. 1A is a schematic top view of a conventional power MOSFET.

FIG. 1B is a schematic top view of the conventional power MOSFET of FIG. 1A with various of the upper metal and dielectric layers omitted so that the gate structure is visible.

FIG. 1C is a schematic cross-sectional view taken along line 1C-1C of FIG. 1B.

FIG. 2A is a schematic top view of the conventional power MOSFET of FIGS. 1A-1C (with the portion of the polyimide protective layer that is above the metal gate runner omitted to show the gate runner) that shows how the on-state currents that flow through unit cells at the top and bottom of the die have extended paths through the source metallization.

FIG. 2B is another schematic top view of the conventional power MOSFET of FIGS. 1A-1C (with the portion of the polyimide protective layer that is above the metal gate runner omitted to show the gate runner) that illustrates the estimated voltage drop for on-state currents that flow through unit cells at the top and bottom of the die as compared to on-state currents that flow through unit cells that are directly underneath the source bond wires.

FIG. 3A is a schematic top view of a silicon carbide power MOSFET according to certain embodiments of the present invention.

FIG. 3B is a schematic top view of the silicon carbide power MOSFET of FIG. 3A with various of the upper metal and dielectric layers removed.

FIG. 3C is a schematic top view of the portion of the silicon carbide power MOSFET of FIGS. 3A-3B shown in the box labelled A in FIG. 3B.

FIG. 3D is a schematic cross-sectional view taken along the line 3D-3D of FIG. 3C with portions of the upper metallization and dielectric layers of the power MOSFET added for context.

FIG. 3E is a schematic cross-sectional view taken along line 3E-3E of FIG. 3B.

FIG. 3F is a schematic cross-sectional view taken along line 3F-3F of FIG. 3B.

FIG. 3G is a schematic top view of the power MOSFET of FIG. 3A that shows how the on-state current can flow through the gaps in the metal gate runner to unit cell transistors that are on the far sides of the gaps.

FIGS. 4-5 are schematic top views of silicon carbide power MOSFETs according to further embodiments of the present invention.

FIG. 6 is a schematic cross-sectional view of a gate trench power semiconductor device according to embodiments of the present invention.

Two-part reference numerals that include a hyphen are used herein in some instances to distinguish between different ones of multiple like elements. The full two-part reference numeral may be used in the description to refer to individual of these elements, while the first part of the reference numeral may be used to refer to the elements collectively.

### DETAILED DESCRIPTION

Adding of metal gate runners to a power semiconductor device involves inherent performance tradeoffs. The gate signal travels more quickly along a metal gate runner, and hence adding metal gate runners increases the switching speed of the device (and thus reduces switching losses). However, the metal gate runners reduce the size of the active region, which increases the on-state resistance of the device, resulting in increased conduction losses. Moreover, the addition of metal gate runners having inner gate runners may also negatively impact the ability to have as many source bond wires as may be desired, which also can negatively impact the performance of the device.

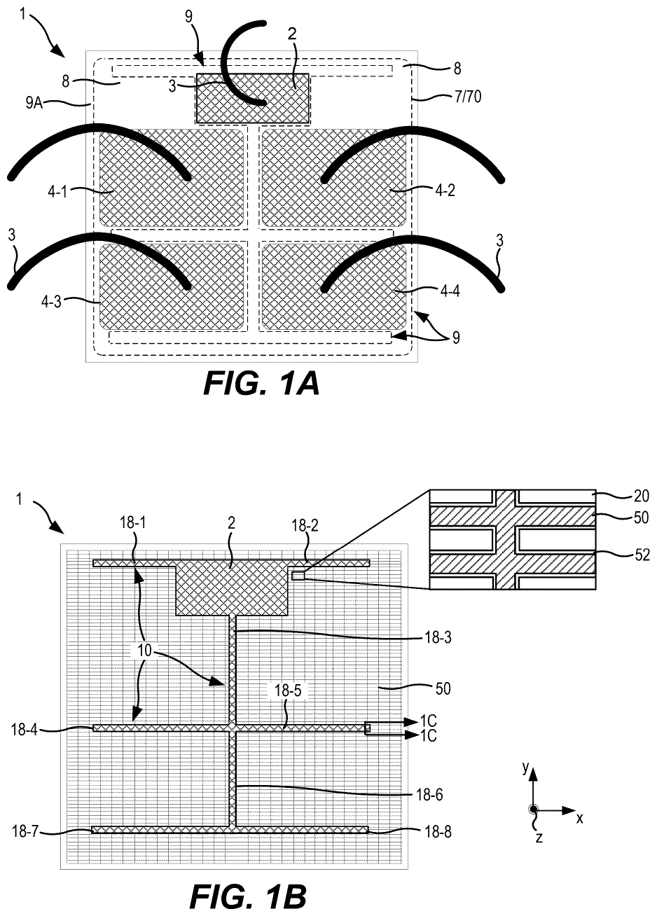

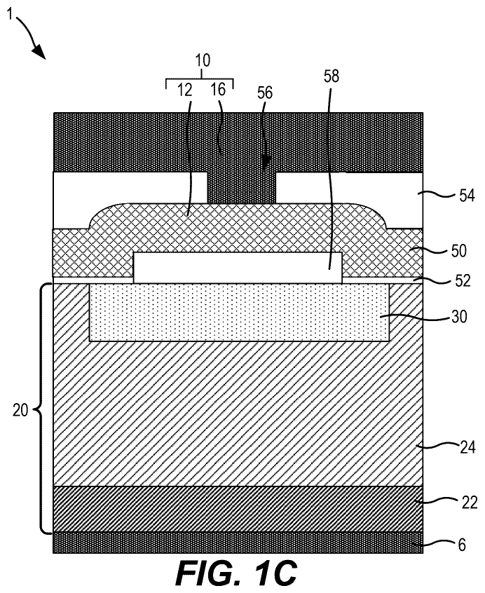

Many power semiconductor devices are fabricated using a single top side metallization layer. For example, in the power MOSFET 1 of FIGS. 1A-1C the gate pad 2, the metal gate runner 16 and the source metallization 70 are all formed from the same metal layer. This approach may reduce manufacturing costs. However, it also means that the source metallization 70 cannot be formed underneath the gate pad 2 and/or formed underneath or on top of the metal gate runner 16. The on-state current enters power MOSFET 1 through the drain terminal 6 on the lower side of the semiconductor layer structure 20 and exits power MOSFET 1 through the source bond wires 3. Unfortunately, one potential consequence of using a single top-side metal layer is that the on-state current cannot flow through the source metallization 70 in the regions of the device where the metal gate runner 16 is formed, and hence the on-state current that enters the source metallization 70 through certain of the unit cell transistors may need to flow around portions of the metal gate runner 16 to reach the source bond wires 3. If a metal gate runner segment 18 is interposed on the “direct path” between the source metallization 70 above a certain unit cell transistor and the nearest source bond wire 3, then the on-state current will either have to flow around the metal gate runner segment 18 or flow to a different source bond wire 3 that is farther away, resulting in a longer on-state current path than would be the case if the metal gate runner segment 18 had been omitted. Since the longer on-state current path will have a higher resistance, the net effect is that inner metal gate runner segments 18 can increase the degree of uneven current distribution during on-state operation. This is disadvantageous for several reasons, as will be discussed in detail below.

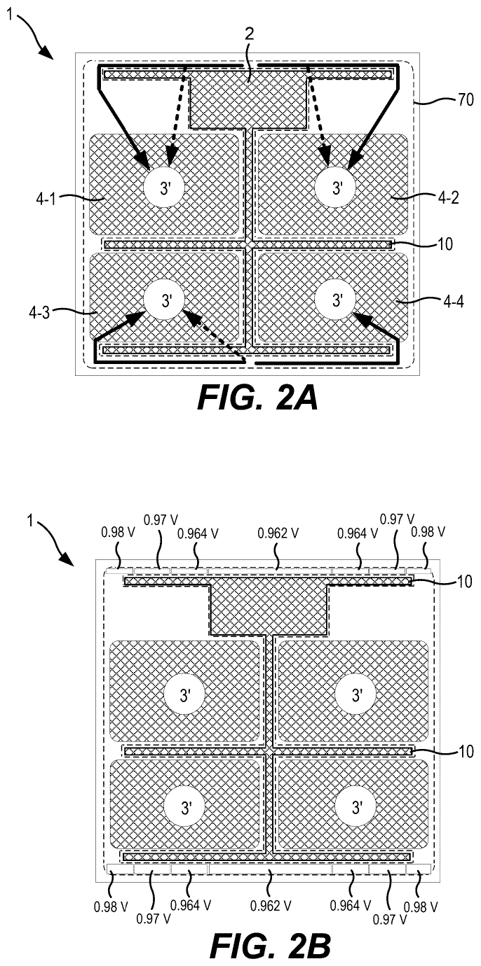

FIGS. 2A-2B illustrate the above-discussed performance disadvantageous that may result from the use of inner metal gate runners. In particular, FIG. 2A is a schematic top view of the conventional power MOSFET 1 of FIGS. 1A-1C that shows how the on-state currents that flow through unit cells at the top and bottom of the die have extended paths through the source metallization 70. FIG. 2B is another schematic top view of the conventional power MOSFET 1 of FIGS. 1A-1C that illustrates the estimated voltage drop for on-state currents that flow through unit cells at the top and bottom of the die as compared to on-state currents that flow through unit cells that are directly underneath the source bond wires. In FIGS. 2A-2B, the circles 3′ illustrate the location where the source bond wires 3 are bonded to the respective source pads 4.

Referring to FIG. 2A, the dashed box labelled 70 shows the portion of the upper surface of the semiconductor layer structure 20 that is covered by the source metallization 70. Note that the active region 7 is provided along the upper and lower (in the view of FIG. 2A) edges of the semiconductor layer structure 20 (i.e., above metal gate runner segments 18-1 and 18-2 and below metal gate runner segments 18-7 and 18-8 in the view of FIG. 2A). Because the source metallization 70 cannot be present in the locations of the first and second metal gate runner segments 18-1, 18-2 (since a single metal layer is used to form both the gate pad 2, the metal gate runner 16 and the source metallization 70) that extend from the sides of the gate pad 2, during on-state operation the on-state current has to flow around the ends of the first and second gate runner segments 18-1, 18-2 to flow between the unit cells along the upper edge of the semiconductor die and the closest source bond wires 3. This may, for example, approximately double the length of the on-state current path to these unit cell transistors as compared to the length of the on-state current path in a comparable power MOSFET that did not include a metal gate runner (shown by the dashed arrow). The exact same effect is seen with respect to the unit cell transistors that are along the lower edge of the semiconductor die.

In particular, when power MOSFET 1 is turned on, the on-state current flows into the semiconductor layer structure 20 through the drain terminal and through the unit cell transistors into the source metallization 70, and exits power MOSFET 1 through the source bond pads 4-1 through 4-4. For unit cell transistors that are directly underneath a source bond wire 3, the length of the current path for on-state current flowing through the source metallization 70 is equal to the thickness of the source metallization 70. For unit cell transistors that are not directly underneath a source bond wire 3, the length of the current path through the source metallization 70 is equal to the distance between the unit cell transistor and the closest source bond wire 3 plus the thickness of the source metallization 70. The amount of on-state current that will flow through any particular unit cell transistor will be a function of the resistance along the current path through that unit cell transistor as compared to the resistances along the current paths through all of the other unit cell transistors. Since the unit cell transistors that are directly underneath the source bond wires 3 have a lower resistance current path, the current density through these unit cells may be higher than the current density through unit cell transistors that are located further from the source bond wires 3.

The impact that the different current path lengths have on the on-state current density is illustrated in FIG. 2B. In particular, FIG. 2B illustrates the voltage of the on-state current at different locations within the source metallization. Since the current (I) and voltage (V) are linearly related as a function of the resistance (R) according to Ohm's Law (V=IR), the voltage levels shown in FIG. 2B may also be viewed as showing the on-state current density in different portions of the power MOSFET 1. In the example of FIG. 2B, it is assumed that this sheet resistance is 7 mO/sq. As can be seen in FIG. 2B, due to the increased on-state current path length, the voltage may drop by about 4% as the on-state current travels between the source bond wires 3 and the unit cell transistors that have the longest on-state current paths as compared to the unit cell transistors that have the shortest on-state current paths (which are the unit cells underneath the circles 3′ in FIG. 2B).

One advantage that outer metal gate runners have over inner metal gate runners is that they never interrupt the “direct path” between a unit cell transistor and the nearest source bond wire since the outer metal gate runners extend around the periphery of the active region. However, when only outer metal gate runners are used, the delay experienced by gate signals in reaching unit cells in the center of the device may be higher, resulting in slower switching speeds. In addition, inner metal gate runners are more efficient in shortening this delay (in terms of the amount of active area sacrificed) as inner metal gate runner segments feed unit cell transistors on both sides of the segment, whereas an outer metal gate runner segment only feeds unit cell transistors on the inner side of the segment. Thus, inner metal gate runners outperform outer metal gate runners in terms of distributing the gate signals, and hence smaller amounts of inner metal gate runner can be used, freeing up extra die area that can be used for implementing unit cell transistors.

Thus, as the above discussion makes clear, the design of the metal gate runner for a power semiconductor device includes a number of tradeoffs in terms of switching speed and on-state current performance and various other performance parameters.

Pursuant to embodiments of the present invention, gate-controlled power semiconductor devices such as power MOSFETs and IGBTs are provided that have improved gate runner designs. At least some of the metal gate runners in power semiconductor devices according to certain embodiments of the present invention may include gaps where the metal is omitted. The gaps may, for example, be in a middle portion of a metal gate runner segment (dividing the metal gate runner segment into two metal gate runner segments), between two metal gate runner segments, or between a metal gate runner segment and the gate pad. The source metallization may extend into and/or above these gaps in order to provide more direct on-state current paths from unit cells on a far side of a gate runner segment to a source bond wire on the other side of the gate runner segment. A polysilicon gate runner that underlies the metal gate runner may electrically connect the metal gate runner segments that are separated by the gap.

The power semiconductor devices according to certain embodiments of the present invention may have various unique features. For example, the source metallization of some power semiconductor devices according to embodiments of the present invention may have an opening therein and a first metal gate runner segment may be positioned within the opening and surrounded by the source metallization when the semiconductor device is viewed from above, while a second metal gate runner segment is positioned outside the opening. As another example, some power semiconductor devices according to embodiments of the present invention may have a primary electrical connection between two metal gate runner segments extend through a non-metal conductive structure such as, for example, a polysilicon gate runner.

The power semiconductor devices according to embodiments of the present invention may have various advantages over conventional power semiconductor devices. As discussed above, by providing gaps in the metal gate runner, the on-state current distribution in the power semiconductor devices may be improved. Improved on-state current distribution may allow the device to support higher on-state currents, and also lowers the on-state resistance of the device (i.e., the source-to-drain resistance during on-state operation), which is an important performance parameter. In addition, more uniform on-state current distributions means that the gate oxide layers of the unit cell transistors may be stressed more uniformly during on-state operation. This may generally improve the reliability of the device, as it may decrease the likelihood that some unit cells have much higher gate oxide stress during on-state operation, which could make those unit cells more likely to fail due to gate oxide breakdown. Moreover, by increasing the number of current paths in the source metallization, the amount of on-state current flowing in any given current path can be reduced. This reduces the temperature increase that may occur on any given current path during various unwanted events (e.g., avalanche breakdown), making it less likely that the device suffers damage during these events. The reduced on-state current levels can also reduce other unwanted effects such as electromigration. Moreover, in some cases, the gaps may eliminate the need for extra source bond wires in edge areas of a device. Fewer source bond wires simplifies the manufacturing process and removes possible points of failure, although using fewer bond wires will decrease the on-state current distribution to some extent.

The gaps in the metal gate runner segments may be “bridged” using, for example, a polysilicon gate runner that underlies the metal gate runner segments, so that gate signals can traverse the gaps. Since the gate signal will travel through polysilicon more slowly than metal, the provision of the gaps will increase the time it takes for the gate signal to reach some unit cell transistors, which may decrease the switching speed of the device. However, the impact on switching speed may be mitigated by locating the gaps in positions where the unit cell transistors served by the metal gate runner segments are somewhat closer to the metal gate runner. In other words, the location of the gaps (as well as the gate runner segments and the source bond wires) may be selected so that the unit cell transistors that have increased gate signal delay times due to the gaps are not the unit cell transistors that would otherwise have the longest gate signal delays.

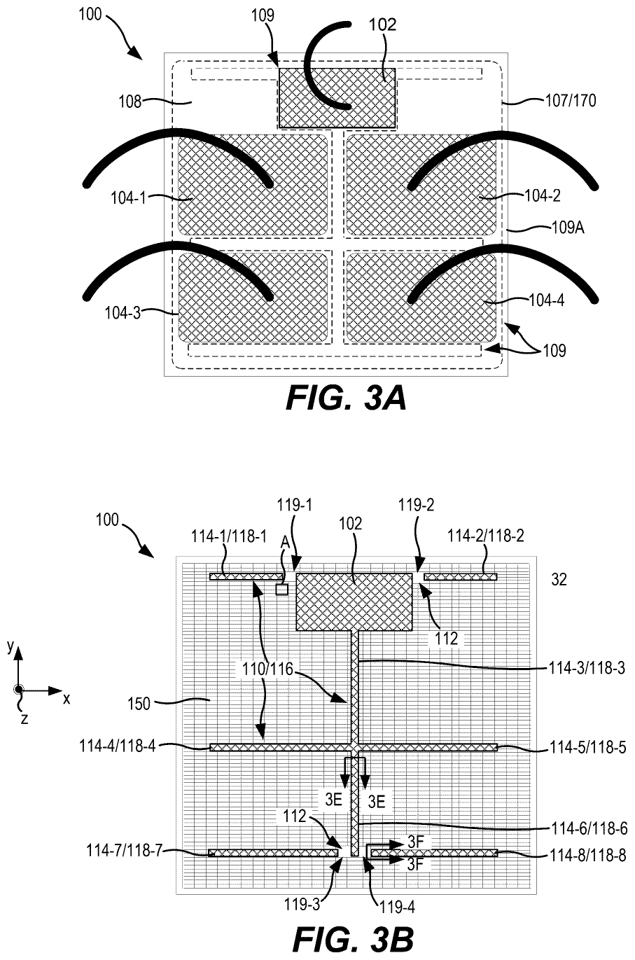

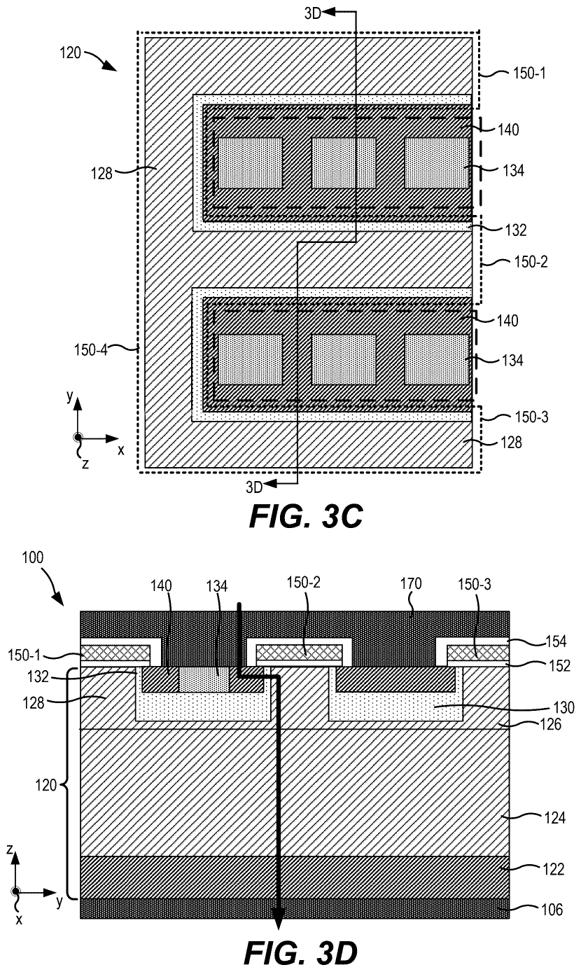

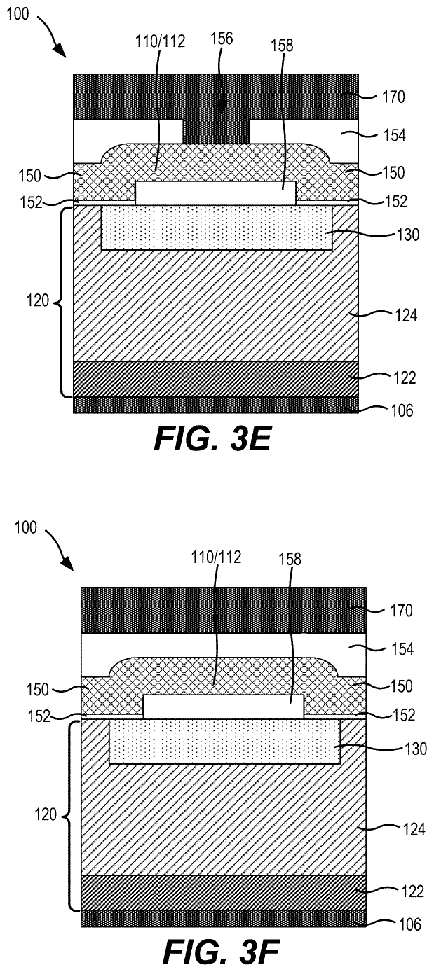

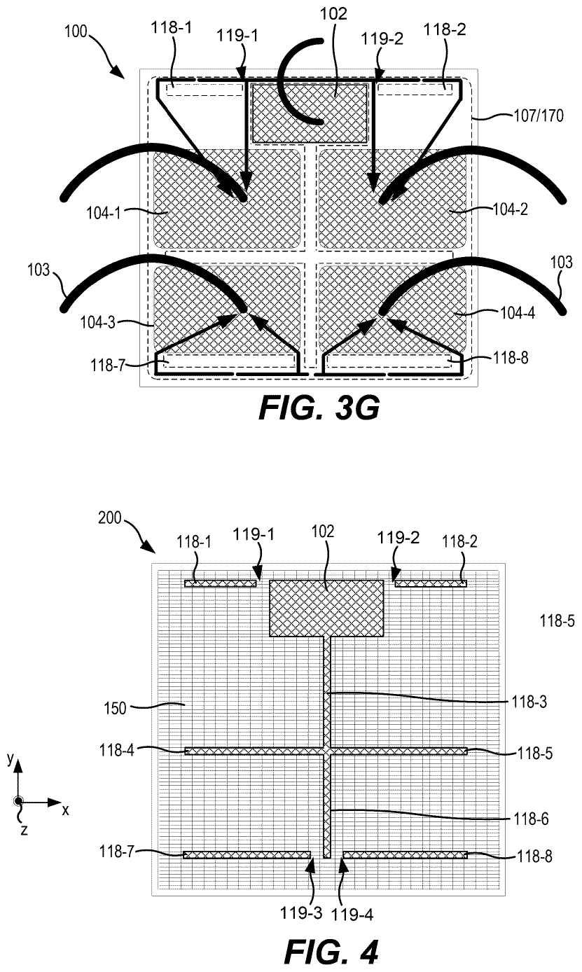

Example embodiments of power semiconductor devices according to embodiments of the present invention will now be described with reference to FIGS. 3A-6. It will be appreciated that features of the different embodiments disclosed herein may be combined in any way to provide many additional embodiments. Thus, it will be appreciated that various features of the present invention are described below with respect to specific examples, but that these features may be added to other embodiments and/or used in place of example features of other embodiments to provide many additional embodiments. Thus, the present invention should be understood to encompass these different combinations. Additionally, while the example embodiments focus on MOSFET implementations, it will be appreciated that the same techniques may be used in other gate trench power semiconductor devices such as insulated gate bipolar transistors (IGBTs), gate-controlled thyristors and the like.

FIG. 3A is a schematic top view of a vertical silicon carbide power MOSFET 100 according to certain embodiments of the present invention. FIG. 3B is a schematic plan view of the power MOSFET 100 with various upper metal and dielectric layers thereof omitted. FIG. 3C is a schematic top view of the portion of the power MOSFET 100 of FIG. 3B shown in the box labelled A in FIG. 3B. FIG. 3D is a schematic cross-sectional view of power MOSFET 100 that is taken along line 3D-3D of FIG. 3C. FIGS. 3E and 3F are schematic cross-sectional views taken along lines 3E-3E and 3F-3F of FIG. 3B. It will be appreciated that the thicknesses of various of the layers and regions in FIGS. 3D-3F are not necessarily drawn to scale. FIG. 3G is a schematic top view of the power MOSFET of FIG. 3A that shows how the on-state current can flow through the gaps in the metal gate runner to unit cell transistors that are on the far sides of the gaps.

The power MOSFET 100 includes a semiconductor layer structure 120 (see FIGS. 3C-3F) that comprises one or more semiconductor substrates and/or layers. At least one (and typically all) of the semiconductor layers in the semiconductor layer structure 120 may be silicon carbide layers. Various semiconductor, metal and/or dielectric layers are formed on either side of the semiconductor layer structure 120 and/or embedded in the semiconductor layer structure 120.

As shown in FIG. 3A, the top-side metal layers include a gate pad 102 and a plurality of source pads 104 that are formed on the upper side of the semiconductor layer structure 120. A total of four source pads 104-1 through 104-4 are shown, but other numbers of source pads 104 may be used. A metal drain pad 106 (see FIGS. 3D-3F) is provided on the bottom side of the semiconductor layer structure 120. The gate pad 102, the source pads 104 and the drain pad 106 form the respective gate, source and drain terminals of power MOSFET 100. The gate and source pads 102, 104 may each be formed of one or more metals, including, for example, a metal such as aluminum that bond wires can be readily attached to via conventional techniques such as ultrasonic heavy wire bonding. Thus, the gate pad 102 and/or the source pads 104 may also be referred to herein as “bond” pads in some cases. The drain pad 106 may likewise be a metal pad. A protective layer 108 such as a polyimide layer may cover the entire upper surface of power MOSFET 100 except for the gate and source pads 102, 104.

The source pads 104 typically comprise portions of a source metallization 170 (described below) that are exposed through openings in the protective layer 108. The source metallization 170 electrically connects certain regions of the semiconductor layer structure 120 to the source pads 104. The source metallization 170 may generally overlie or correspond to an “active region” 107 of power MOSFET 100 where the unit cell transistors are located. The dashed lines in FIG. 3A illustrate the location of the active region 107 since it is underneath the metal pads 102, 104 and the protective layer 108. The remainder of the semiconductor layer structure 120 may comprise an inactive region 109. The inactive region 109 includes a termination region 109A that extends at least part of the way around the periphery of power MOSFET 100 to at least partly surrounds the active region 107. The termination region 109A does not include any active unit cells. The termination region 109A may comprise one or more termination structures (not shown in FIG. 3A) such as guard rings or a junction termination extension region. Bond wires are shown in FIG. 3A that may be used to connect the gate pad 102 and the source pads 104 to external circuits or the like. The drain pad 106 on the bottom side of power MOSFET 100 may be connected to an external circuit through, for example, an underlying submount (not shown). The inactive region 109 (indicated by the dashed region in FIG. 3A) also includes the region of the semiconductor layer structure 120 where the gate pad 102 and a metal gate runner 116 (discussed below) are formed.

FIG. 3B is another plan view of power MOSFET 100 with the source pads 104, the polyimide layer 108, the source metallization 170, and various dielectric layers omitted to show the gate electrodes 150 that are formed on the upper surface of the semiconductor layer structure 120 and a gate runner 110 that electrically connects the gate pad 102 to the gate electrodes 150. The gate runner 110 includes a polysilicon gate runner 112 and a metal gate runner 116, where the polysilicon gate runner 112 (FIGS. 3E-3F) is between the semiconductor layer structure 120 and the metal gate runner 116. The gate runner 110 is implemented as an inner gate runner with no outer gate runner provided. It will be appreciated, however, that in other embodiments an outer gate runner may be added.

As shown in FIG. 3B, the metal gate runner 116 electrically connects the gate pad 102 to the gate electrodes 150, which extend throughout the active region 107. The gate electrodes 150 have a mesh structure where both horizontally-extending and vertically-extending gate electrodes 150 are provided. The polysilicon gate runner 112 includes eight distinct segments 114, namely a first segment 114-1 that extends to the left from the upper left corner of the gate pad 102, a second segment 114-2 that extends to the right from the upper right corner of the gate pad 102, a third segment 114-3 that extends from the lower center of the gate pad 102, a sixth segment 114-6 that extends from a distal end of the third segment 114-3, a fourth segment 114-4 that extends to the left from the intersection of the third and sixth segments 114-3, 114-6, a fifth segment 114-4 that extends to the right from the intersection of the third and sixth segments 114-3, 114-6, a seventh segment 114-7 that extends to the left from the distal end of the sixth segment 114-6, and an eighth segment 114-8 that extends to the right from the distal end of the sixth segment 114-6. The third through eighth segments 114-3 through 114-8 have a spine and rib configuration in which a spine (namely the third and sixth segments 114-3, 114-6) extends from the gate pad 102 and a plurality of ribs (namely the third and fifth and seventh and eighth segments 114-4, 114-5, 114-7, 114-8) extend from each side of the spine. The lengths of the ribs may be adjusted to meet a specific gate resistance target, and the distance between the end of each rib and an adjacent edge of the active region may impact current crowding, so the length of the ribs may also be adjusted based on current crowding considerations.

The metal gate runner 116 is similar to the polysilicon gate runner 112, except that four gaps 119-1 through 119-4 are formed where the metal of the metal gate runner 116 is omitted (and replaced with source metallization 170, as will be discussed in further detail below). As a result, the metal gate runner 116 includes eight distinct segments 118, namely a first metal gate runner segment 118-1 that extends to the left from the upper left corner of the gate pad 102, a second metal gate runner segment 118-2 that extends to the right from the upper right corner of the gate pad 102, a third metal gate runner segment 118-3 that extends from the lower center of the gate pad 102, a sixth metal gate runner segment 118-6 that extends from a distal end of the third metal gate runner segment 118-3, a fourth metal gate runner segment 118-4 that extends to the left from the intersection of the third and sixth metal gate runner segments 118-3, 118-6, a fifth metal gate runner segment 118-4 that extends to the right from the intersection of the third and sixth metal gate runner segments 118-3, 118-6, a seventh metal gate runner segment 118-7 that extends to the left from the distal end of the sixth metal gate runner segment 118-6, and an eighth metal gate runner segment 118-8 that extends to the right from the distal end of the sixth metal gate runner segment 18-6. The third through eighth metal gate runner segments 118-3 through 118-8 have a spine and rib configuration in which a spine (namely the third and sixth metal gate runner segments 118-3, 118-6) extends from the gate pad 102 and a plurality of ribs (namely the third and fifth and seventh and eighth metal gate runner segments 118-4, 118-5, 118-7, 118-8) extend from each side of the spine.

As shown in FIG. 3B, the gaps 119 are only formed in the metal gate runner 116. In other words, the polysilicon gate runner 112 does not include corresponding gaps so that the polysilicon gate runner 112 may be identical to the polysilicon gate runner 12 of power MOSFET 1 that is discussed above with reference to FIGS. 1B-1C. When a gate signal is applied to the gate pad 102 of power MOSFET 100, the gate current flows into the third metal gate runner segment 118-3 and from there into the fourth through sixth metal gate runner segments 118-4 through 118-6 (following the low-resistance current path), and then travels generally vertically through the portions of the polysilicon gate runner 112 that underlie the third through sixth metal gate runner segments 118-3 through 118-6. At the locations of the gaps 119, the gate current flows from the gate pad 102 (for gaps 119-1 and 119-2) and from the sixth metal gate runner segment 118-6 into the polysilicon gate runner 112 so that the gate signal can flow through the portions of the polysilicon gate runner 112 that underlie the respective gaps 119. At the far side of each gap 119, the gate signal will flow from the polysilicon gate runner 112 into the first, second, seventh and eighth metal gate runner segments 118-1, 118-2, 118-7 and 118-8 and flow along the length of those segments. The gate current that flows along into the first, second, seventh and eighth metal gate runner segments 118-1, 118-2, 118-7 and 118-8 will then travel generally vertically through the portions of the polysilicon gate runner 112 that underlie the first, second, seventh and eighth metal gate runner segments 118-1, 118-2, 118-7 and 118-8.

Thus, as the above discussion makes clear, gate signals that are applied to the gate pad 102 may flow through the entire gate runner 110, even though four gaps 119 are provided in the metal gate runner 116, since the portions of the polysilicon gate runner 112 underlying each gap 119 acts to “bridge” the gap 119 (i.e., provides a current path connecting the portions of the metal gate runner 116 and/or metal gate pad 102 on either side of the gaps 119). Thus, the gate signal is able to use the gate runner 110 to quickly spread throughout the active region 107, ensuring that power MOSFET 100 has a fast switching speed. The gaps 119 do slow down the portions of the gate signal that flow into the first, second, seventh and eighth metal gate runner segments 118-1, 118-2, 118-7 and 118-8, since the gate signal must flow into the polysilicon gate runner 112 to bridge each gap 119. However, since the gaps 119 are small, the overall decrease in switching speed that occurs due to the presence of the gaps 119 may be acceptable.

FIG. 3C is a schematic top view of the upper surface of the semiconductor layer structure 120 of the portion of the silicon carbide power MOSFET 100 of FIG. 3B that is shown in the box labelled A in FIG. 3B. The dotted region in FIG. 3C illustrate the locations of the gate electrodes 150 that are formed on the upper surface of the semiconductor layer structure 120 (with a gate oxide layer 152 interposed between each gate electrode 150 and the upper surface of the semiconductor layer structure 120). As can be seen in FIG. 3C, the region labeled A in FIG. 3B includes three horizontally-extending gate electrodes 150-1 through 150-3 and one vertically extending gate electrode 150-4. It will be appreciated that the horizontally and vertically extending gate electrodes 150 merge into each other so that the gate electrodes 150 may comprise a continuous monolithic gate electrode. The dashed regions in FIG. 3C illustrate the locations where the source metallization 170 directly contacts the upper surface of the semiconductor layer structure 120.

FIG. 3D is a cross-sectional view taken along line 3D-3D of FIG. 3C. It should be noted that the cross-section of FIG. 3D is not taken along a straight line but instead includes a “jog” to show cross-sections of two different regions of power MOSFET 100.

Referring to FIGS. 3C-3D, the power MOSFET 100 includes an n-type silicon carbide semiconductor substrate 122 such as, for example, a single crystal 4H silicon carbide semiconductor substrate that is heavily-doped with n-type impurities. The n-type doping concentration of the substrate 122 may be, for example, between 1×10¹⁸ atoms/cm³ and 1×10²¹ atoms/cm³, although other doping concentrations may be used. Herein, the “doping concentration” of a semiconductor material refers to the number of dopant atoms that cause the semiconductor material to have a certain conductivity type (i.e., either n-type or p-type) that are present within a cubic centimeter of semiconductor material as measured using standard measurement techniques such as Secondary Ion Mass Spectrometry (“SIMS”). The doping concentration of a layer or region may be relatively constant or may vary (e.g., be graded with depth), and the doping concentration refers to the peak doping concentration of the layer or region. For an n-type semiconductor material, references to the doping concentration refer to the concentration of n-type dopants and for a p-type semiconductor material, references to the doping concentration refer to the concentration of p-type dopants. The substrate 122 may be any appropriate thickness (e.g., between 100 and 500 microns thick), and it will be appreciated that the substrate 122 will typically be much thicker than shown. The thickness of various other layers of power MOSFET 100 likewise may not be shown to scale in order to allow other portions of the devices to be enlarged in the figures. The substrate 122 may be partially or fully removed in some embodiments.

A lightly-doped n-type silicon carbide drift region 124 is provided on the upper surface of the substrate 122. The n-type silicon carbide drift region 124 may be formed by, for example, epitaxial growth on the silicon carbide substrate 122. The n-type silicon carbide drift region 124 may have, for example, a doping concentration of 1×10¹⁴ to 5×10¹⁶ dopants/cm³. The doping concentration may vary with the voltage blocking rating of the device, with devices having higher voltage blocking ratings typically having lower doping concentrations in the drift region 124. For example, a MOSFET 100 having a voltage blocking rating of 10 kV or more might have a drift region n-type doping concentration of between 1×10¹⁴ to 5×10¹⁴ dopants/cm³, whereas a MOSFET 100 having a voltage blocking rating of 500-1200 V might have a drift region n-type doping concentration of between 1×10¹⁶ to 5×10¹⁶ dopants/cm³. The n-type silicon carbide drift region 124 may be a thick region, having a vertical height above the substrate 122 of, for example, 3-50 microns. An upper portion of the n-type silicon carbide drift region 124 may be more heavily doped than the remainder of the drift region 124 to provide a current spreading layer 126 in an upper portion of the drift region 124. The doping concentration of this current spreading layer 126 may be, for example, about 1.5 to 4.0 times higher than the doping concentration of the remainder of the drift region 124. The current spreading layer 126 may be formed during the epitaxial growth process. Herein, the current spreading layer 126, if provided, is considered to be part of the drift layer 124 and hence will not be discussed separately.

A plurality of p-type well regions 130 (which may also be referred to herein as “p-wells”) are formed on upper portions of the n-type drift region 124. While not shown in the figures, a large p-well 130 may also be formed underneath the portion of the field oxide layer 158 that underlies the gate pad 102, and p-wells 130 may also be formed underneath the polysilicon gate runner 112 (see FIGS. 3E-3F). The p-wells 130 may all be interconnected in some embodiments. The p-wells 130 may have a doping concentration of, for example, between 5×10¹⁵ cm⁻³ and 5×10¹⁹ cm⁻³ and, more typically, between 5×10¹⁶ cm⁻³ and 5×10¹⁹ cm⁻³. The p-wells 130 may be formed via ion implantation. As known to those skilled in the art, ions such as n-type or p-type dopants may be implanted in a semiconductor layer or region by ionizing the desired ion species and accelerating the ions at a predetermined kinetic energy as an ion beam towards the surface of a semiconductor layer in an ion implantation target chamber. Based on the predetermined kinetic energy, the desired ion species may penetrate into the semiconductor layer. The ions will implant at different depths into the semiconductor layer so that the predetermined kinetic energy will provide an implant “profile” with varying ion concentrations as a function of depth. The dopants may comprise, for example, Al⁺ or N⁺ ions, although any appropriate dopant ions may be used. In some embodiments, the implantation may be performed at different temperatures such as, for example, temperatures of 75° C. or more. It will be appreciated that the p-wells 130 often have a doping concentration that varies with depth. The p-wells 130 in the active 107 include channel regions 132 (discussed in more detail below) formed therein. These channel regions 132 may be less heavily doped than other portions of the p-well 130 in some embodiments.

A plurality of n-type JFET regions 128 are defined in the upper portion of the drift region 124 between adjacent p-wells 130 underneath the gate electrodes 150. Each JFET region 128 may comprise a region of n-type material and may or may not be more heavily doped n-type than the lower portion of the drift region 124.

A plurality of heavily-doped n-type silicon carbide source regions 140 are formed in upper portions of the p-wells 130. The source region 140 may have a doping concentration of, for example, between 5×10¹⁸ cm⁻³ and 5×10²¹ cm⁻³. In addition, heavily-doped p-type silicon carbide well contact regions 134 are also formed on upper portions of the p-wells 130. As shown, the well contact regions 134 may appear as a plurality of “islands” in each source region 140 when the MOSFET 100 is viewed in plan view. It will be appreciated, however, that in other embodiments the well contact regions 134 may connect to each other along the x-direction so that a single elongated well contact region 134 is provided between each pair of adjacent gate electrodes 150. Other configurations for the well contact and source regions 134, 140 are known in the art and may be used. The well contact regions 134 and the source regions 140 may each be formed via ion implantation. The substrate 122, the drift region 124 (including any current spreading layer 126 and the JFET regions 128), the p-wells 130 (including the channel regions 132 and the well contact regions 134) and the source regions 140 together comprise the semiconductor layer structure 120 of MOSFET 100.

As shown in FIG. 3D, gate dielectric layers 152 are formed on the upper surface of the semiconductor layer structure 120. The gate dielectric layers 152 may or may not be connected to each other along the periphery of the MOSFET 100. The gate dielectric layers 152 may comprise, for example, silicon oxide layers, although other insulating materials may be used. The gate electrodes 150 are formed on the respective gate dielectric layers 152 so that the gate dielectric layers electrically insulate the gate electrodes 150 from the semiconductor layer structure 120. The gate electrodes 150 may comprise, for example, a conductive material such as polysilicon, a silicide or a metal. As discussed above, the gate electrodes 150 may be part of a larger polysilicon pattern that includes the polysilicon gate runner 112. One or more intermetal dielectric layers 154 may cover the respective gate electrodes 150. The intermetal dielectric layers 154 may comprise, for example, silicon oxide.

The upper surface of the semiconductor layer structure 120 is exposed in between adjacent intermetal dielectric patterns 154. The source regions 140 and the p-type well contact regions 134 are thus exposed in between adjacent intermetal dielectric patterns 154. The source metallization 170 is formed over the upper surface of the MOSFET 100 so that the source metallization 170 makes electrical contact to the n-type source regions 140 and the p-type well contact regions 134 while being electrically insulated from the gate electrodes 150 by the intermetal dielectric patterns 154. The source metallization 170 may comprise, for example, an ohmic contact layer such as a silicide layer that directly contacts the semiconductor layer structure 120 and a bulk metal layer (e.g., an aluminum layer) that is on the ohmic contact layer opposite the semiconductor layer structure 120. The source metallization 170 may include additional layers such as barrier layers, adhesion layers, grain stop layers and the like. A drain contact 106 is formed on the lower surface of the substrate 122. The drain contact 106 may comprise, for example, the same or similar materials to the source metallization 170, and may form an ohmic contact to the silicon carbide substrate 122.

FIG. 3E is a cross-sectional view taken along line 3E-3E of FIG. 3B that illustrates how the gate runner 110 connects to the gate electrodes 150. As shown in FIG. 3E, a field oxide layer 158 is formed on the upper surface of the semiconductor layer structure 120 and the polysilicon gate runner 112 is formed on an upper surface of the field oxide layer 158 so that the field oxide layer 158 is between the polysilicon gate runner 112 and the semiconductor layer structure 120. A p-well 130 is formed underneath the field oxide layer 158 and vertically overlaps the field oxide layer 158 and the polysilicon gate runner 112. As used herein, two elements of a semiconductor device are considered to “vertically overlap” if an axis that is perpendicular to the major surfaces of a semiconductor layer structure of the semiconductor device intersects both elements. The intermetal dielectric layer 154 is formed on the polysilicon gate runner 112. A longitudinally-extending via 156 is provided in the intermetal dielectric layer 154 that exposes the upper surface of a central portion of the polysilicon gate runner 112. The metal gate runner 116 is formed on the intermetal dielectric layer 154 and also fills the longitudinally-extending via 156 so that the metal gate runner 116 physically and electrically contacts the polysilicon gate runner 112. The metal gate runner 116 vertically overlaps the polysilicon runner 112. Gate electrodes 150 are formed on either side of the gate runner 110. The gate electrodes 150 are formed on the gate dielectric layers 152, where the gate dielectric layers 152 may be much thinner (e.g., 1/10^{th} the thickness) than the field oxide layer 158. Consequently, the outer edges of the polysilicon gate runner 112 extend downwardly onto the gate dielectric layers 152 so that the polysilicon gate runner 112 merges into the ends of the gate electrodes 150 as shown. This design allows gate signals to flow from the polysilicon gate runner 112 into the gate electrodes 150 as shown.

FIG. 3F is a schematic cross-sectional view taken along line 3F-3F of FIG. 3B that illustrates how source current paths are provided above each gap 119 in the metal gate runner 116. As can be seen by comparing FIGS. 3E and 3F, in the regions of the gaps 119 the metal gate runner 116 is omitted and the intermetal dielectric layer 154 may fully cover the polysilicon gate runner 112. The source metallization 170 is formed on the intermetal dielectric layer 154 above the polysilicon gate runner 112. The intermetal dielectric layer 154 electrically insulates the source metallization 170 from the polysilicon gate runner 112. As shown in FIG. 3F, the source metallization 170 extends into the region of the gap 119 to electrically connect the portion of the source metallization 170 that is on the first side of the gap 119 to the portion the source metallization 170 that is on the second side of the gap 119. In other words, a source current path is provided through each gap 119.

As discussed above, it is desirable to have the on-state current density be as uniform as possible. The uniformity of the on-state current density is a function of the on-state resistance along each on-state current path through power MOSFET 100. Unit cell transistors that are physically located at larger distances from the locations where the source bond wires 103 attach to the source metallization 170 will have higher on-state resistance values, since the on-state current travelling through these unit cells will not only need to travel vertically (i.e., in the z-direction) through the device, but will also need to travel in the horizontal direction within the source metallization 170 to flow to the closest source bond wire 103.

FIG. 3G is a schematic top view of the power MOSFET 100 that shows how the on-state current can flow through the gaps 119 in the metal gate runner 116 to unit cell transistors that are on the far sides of the gaps 119. In FIG. 3G, the dashed regions correspond to the location of the metal gate runner 116.

As can be seen by comparing FIGS. 2A and 3G, the gaps 119 shorten the on-state current paths to the unit cell transistors that have the longest on-state-current paths by about 50%. As a result, the on-state current distribution of power MOSFET 100 may be improved as compared to power MOSFET 1. Having more uniform on-state current density is advantageous for two reasons. First, generally speaking, the larger the current level in any region of the device, the more heating that occurs, and excessive heating can degrade device performance and/or cause reliability issues. Thus, if the on-state current distribution is uniform, then heating of the device may be more uniform and the negative effects of excessive heating may be reduced. Second, the current and voltage ratings for a power semiconductor device are often set to ensure that the device meets certain reliability specifications. Since failure of any unit cell may damage or destroy a power semiconductor device, the current and voltage ratings may be set based on the unit cells that carry the highest on-state currents, as these may be the cells that are most likely to fail. If the current distribution is made more uniform, then the device may, for a given current rating, have improved reliability performance, since increased on-state current may flow through unit cells that had lower on-state current levels in less efficient designs

As the above discussion makes clear, pursuant to some embodiments of the present invention, semiconductor devices such as power MOSFET 100 are provided that comprise a semiconductor layer structure 120 that comprises at least one wide bandgap semiconductor layer (e.g., a silicon carbide layer). A metal gate pad 102 is provided on the semiconductor layer structure 120. Power MOSFET 100 further include a gate runner 110 that is electrically connected to the metal gate pad 102, the gate runner 110 comprising a polysilicon gate runner 112 and a metal gate runner 116 that is on top of the polysilicon gate runner 112 opposite the semiconductor layer structure 120. A gap 119 is provided in the metal gate runner 116 above a first portion of the polysilicon gate runner 112, where the gap 119 separates the metal gate runner 116 into first and second metal gate runner segments (e.g., metal gate runner segments 118-6 and 118-7 or 118-8) or separates a metal gate runner segment (e.g., metal gate runner segments 118-1 or 118-2) from the metal gate pad 102.

In some embodiments, the gap 119 separates the metal gate runner 116 into at least first and second metal gate runner segments (e.g., metal gate runner segments 118-6 and 118-7), and the first portion of the polysilicon gate runner 112 (i.e., the portion of the polysilicon gate runner 112 below the gap 119) electrically connects the two metal gate runner segments 118-6 and 118-7. The power MOSFET 100 further includes a source metallization 170 on the semiconductor layer structure 120, wherein a portion of the source metallization 170 extends above and vertically overlaps the gap 119.

Power MOSFET 100 further comprises a source bond wire 103 that is electrically connected to the source metallization 170, where the source bond wire 103 is on a first side of the gap 119 when power MOSFET 100 is viewed from above. Power MOSFET 100 further includes a first unit cell transistor that is on a second, opposed, side of the gap 119 when power MOSFET 100 is viewed from above. During on-state operation, a primary current path for the source-drain on-state current that flows between the first unit cell transistor and the source bond wire 103 is through the portion of the source metallization 170 that extends above and vertically overlaps the gap 119. Herein, a “primary current path” that connects first and second conductive structures (where here the first and second conductive structures are the first unit cell transistor and the source bond wire 103) refers to a path that will carry at least half of a current flowing between the first and second conductive structures under normal device operation.

As shown in FIG. 3G, the source metallization 170 includes a first opening when power MOSFET 100 is viewed from above, and metal gate runner segment 118-7 is within the first opening and surrounded by the source metallization 170. In contrast, the remaining metal gate runner segments 118-1 through 118-6 and 118-8 are not within the first opening in the source metallization 170, although metal gate runner segments 118-1, 118-2 and 118-8 are each within respective additional openings in the source metallization 170.

As discussed above, a plurality of gaps 119 are provided in the metal gate runner 116 of power MOSFET 100. For example, a second gap (e.g., gap 119-2) is provided that separates a segment 118 of the metal gate runner 116 from the metal gate pad 102, and the polysilicon gate runner 112 is provided beneath the second gap 119-2, and the source metallization 170 extends above the second gap 119-2.

As discussed above, the gaps 119 may be small. For example, a first distance between the first and second metal gate runner segments 118 across the gap 119 may be less than 10%, or less than 5%, a length of a longest side of the semiconductor layer structure 120 (here the semiconductor layer structure 120 has a square shape when viewed from above, so all four sides thereof have the same length).

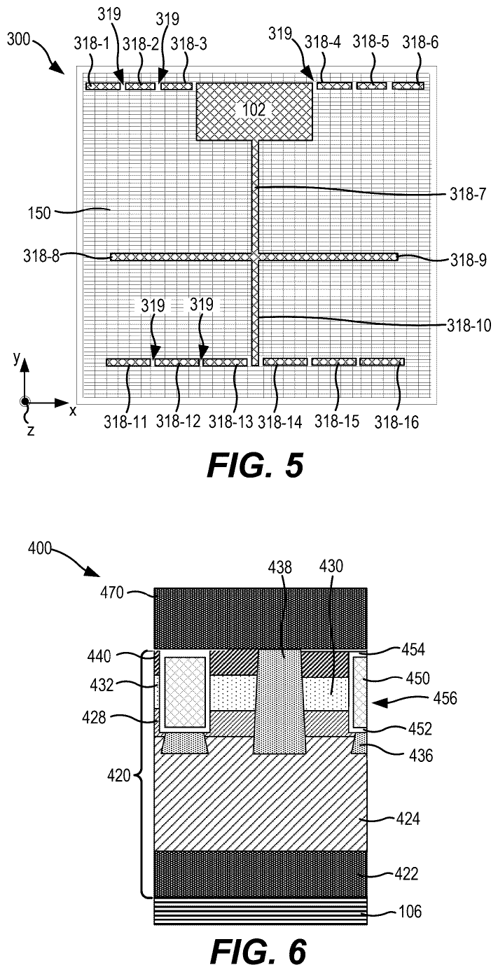

In some cases, two metal gate runner segments (e.g., metal gate runner segments 118-6 and 118-7) that are separated by a gap 119 may be perpendicular to each other (i.e., the metal gate runner segment 118-6 extends along a first longitudinal axis and the metal gate runner segment 118-7 extends along a second longitudinal axis that is perpendicular to the first longitudinal axis). In other embodiments, as will be discussed below with reference to FIG. 5, two metal gate runner segments 118 that are separated by a gap 119 may be collinear metal gate runner segments 118 (i.e., both segments extend in their longitudinal directional along a common axis).

As shown in FIGS. 3A-3B, the gate runner 110 may include an inner gate runner that has a spine and rib configuration that comprises a spine and a plurality of ribs. As is also shown, the gaps 119 may be provided in between the spine and one or more of the ribs so that at least some of the ribs only connect to the spine through the polysilicon gate runner 112 and not through the metal gate runner 116.

Pursuant to further embodiments of the present invention, semiconductor devices are provided (e.g., power MOSFET 100) that comprise a semiconductor layer structure 120, a metal gate pad 102 on the semiconductor layer structure 120, and a metal gate runner 116 on the semiconductor layer structure 120. The metal gate runner 116 comprises first and second metal gate runner segments (e.g., segments 118-6 and 118-7) that are spaced-apart from each other by a gap (e.g., gap 119-3) where a primary electrical connection between the metal gate runner segment 118-7 and the metal gate pad 102 is through the metal gate runner segment 118-6. Herein, references to a “primary electrical connection” between first and second conductive structures (where here the first and second conductive structures are the metal gate runner segment 118-7 and the metal gate pad 102) refers to an electrical connection that will carry at least half of a current flowing between the first and second conductive structures under normal device operation. Here the current is a gate-to-source capacitive current.

Pursuant to additional embodiments of the present invention, semiconductor devices are provided (e.g., power MOSFET 100) that comprise a semiconductor layer structure 120, a metal gate pad 102 on the semiconductor layer structure 120, and a metal gate runner 116 on the semiconductor layer structure 120. The metal gate runner 116 includes a metal gate runner segment (e.g., segment 118-1) that is spaced-apart from the gate pad 102 by a gap (e.g., gap 119-1). Power MOSFET 100 further comprises a polysilicon structure (here polysilicon gate runner 112) on the semiconductor layer structure 120 that electrically connects the gate pad 102 to the metal gate runner segment 118-1. In some embodiments, at least a portion of the gate pad 102 may vertically overlap a part of the polysilicon structure.

Pursuant to still further embodiments of the present invention, semiconductor devices are provided (e.g., power MOSFET 100) that comprise a semiconductor layer structure 120, a metal gate pad 102 on the semiconductor layer structure 120, a source metallization 170 on the semiconductor layer structure 120, and a metal gate runner 116 on the semiconductor layer structure 120. The metal gate runner 116 comprises at least first and second metal gate runner segments 118 (e.g., segments 118-6 and 118-7). The source metallization 170 comprises a first opening when viewed from above, and the first metal gate runner segment (segment 118-7) is within the opening and the second metal gate runner segment 118-6 is outside the opening when power MOSFET 100 is viewed from above.

Pursuant to yet additional embodiments of the present invention, semiconductor devices are provided (e.g., power MOSFET 100) that comprise a semiconductor layer structure 120, a metal gate pad 102 on the semiconductor layer structure 120, and a metal gate runner 116 on the semiconductor layer structure 120. The metal gate runner 116 comprises an inner metal gate runner that has a spine (here metal gate runner segments 118-3 and 118-6) that has a first end that is electrically connected to the gate pad 102 and a plurality of ribs (here metal gate runner segments 118-4, 118-5, 118-7 and 118-8) that extend perpendicularly from the spine 118-3, 118-6. A first of the ribs (e.g., rib 118-7) is separated from the spine 118-3, 118-6 by a gap 119-3 and is electrically connected to the spine 118-3, 118-6 by a conductive structure (here polysilicon gate runner 112) that underlies the gap 119-3.

Pursuant to further embodiments of the present invention, semiconductor devices are provided (e.g., power MOSFET 100) that comprise a semiconductor layer structure 120 and a metal gate structure on the semiconductor layer structure, the metal gate structure comprising a metal gate pad 102 and a metal gate runner 116. A first gap 119 is provided in the metal gate structure where metal is omitted so that a first portion of the metal gate structure (e.g., metal gate runner segment 118-1) is spaced apart from a second portion of the metal gate structure (e.g., metal gate pad 102) by the first gap 119-1. The first portion of the metal gate structure is electrically connected to the second portion of the metal gate structure via a conductive structure that is below the first gap 119-1. The conductive structure may comprise, for example, the polysilicon gate runner 112.

As discussed above, the gaps 119 in the metal gate runner 116 act to increase the time that it takes a gate signal applied to the gate pad 102 to reach a set gate voltage during device turn-on at selected of the unit cell transistors. In particular, since the gate signal will travel more slowly through the polysilicon gate runner 112 than it will through the metal gate runner 116, the gate signal will arrive more slowly at the unit cell transistors that are fed by the first, second, seventh and eighth metal gate runner segments 118-1, 118-2, 118-7 and 118-8 as compared to the corresponding unit cell transistors in conventional power MOSFET 1 of FIGS. 1A-1C. This may be undesirable for at least two reasons. First, the increased delay reduces the switching speed of power MOSFET 100 since the added delay means that it takes the MOSFET 100 longer to turn on or off. Second, because the unit cells turn on and off at different times, some unit cells may experience higher electric field levels than others. This may reduce the reliability of the device. However, since the gate signal already flows through long stretches of polysilicon (namely through the gate electrodes 150) to reach unit cell transistors that are far from the gate runner 110, the provision of the small gaps 119 in the metal gate runner 116 may not have a significant negative impact.

Generally speaking, inner gate runner segments are more effective than outer gate runner segments at decreasing the time it takes the gate signal to reach unit cells in the middle of a die, both because inner gate runner segments may be routed closer to unit cell transistors in the middle of the die and because inner gate runner segments connect to polysilicon gate electrodes on both sides thereof. However, as described above, inner gate runner segments can also force the on-state source current to travel along longer current paths or require a larger number of source bond wires, both of which are undesirable. By including small gaps 119 in the metal gate runner 116, larger inner metal gate runners (and less outer metal gate runners) may be included in a device, which can result in improved overall performance in terms of switching speed, device power rating and device reliability.

In the embodiment of FIGS. 3A-3G, the polysilicon gate runner 112 is used to “bridge” the gaps 119 to electrically connect the metal gate runner segments 118 on the far side of the gaps 119 to the metal gate pad 102 (either directly, or through another metal gate runner segment 118). It will be appreciated, however, that embodiments of the present invention are not limited thereto. For example, FIG. 4 is a schematic plan view (corresponding to FIG. 3B) of a power MOSFET 200 that is slightly modified version of power MOSFET 100. As can be seen by comparing FIGS. 3B and 4, the only difference between the two power MOSFETS 100, 200 is that in power MOSFET 200 the polysilicon gate runner 112 is also omitted in the gaps 119 and replaced with unit cell transistors. The gate electrodes 150 of the unit cell transistors in the gaps 119 provides the conductive path between the metal gate runner segments 118 on the far side of the gaps 119 to the metal gate pad 102 (either directly, or through another metal gate runner segment 118). This approach advantageously increases the percentage of the die that is devoted to active unit cell transistors, but uses a higher resistance connection between the metal gate runner segments 118 on the far side of the gaps 119 to the metal gate pad 102, which reduces the switching speed of the device and/or increases the overall gate resistance.

Thus, referring to FIG. 4, pursuant to other embodiments of the present invention, semiconductor devices are provided (e.g., power MOSFET 200) that comprise a semiconductor layer structure 120, a metal gate pad 102 on the semiconductor layer structure 120, and a metal gate runner 116 on the semiconductor layer structure 120. The metal gate runner 116 comprises first and second metal gate runner segments (e.g., metal gate runner segments 118-6, 118-7) that are separated from each other by a gap 119. Power MOSFET 200 further includes a plurality of polysilicon gate electrodes 150 on the semiconductor layer structure 120. Moreover, a primary electrical connection between the second metal gate runner segment (e.g., metal gate runner segment 118-7) and the metal gate pad 102 is through one or more of the polysilicon gate electrodes 150. In some embodiments, the gap 119 may vertically overlap the gate electrodes 150.

The metal gate runner 116 is part of a gate runner 110 that is electrically connected to the metal gate pad 102. The gate runner 110 further comprises a polysilicon gate runner 112 that is in between the metal gate runner 116 and the semiconductor layer structure 120. The polysilicon gate runner 112 is a first part of a polysilicon pattern and the polysilicon gate electrodes 150 are a second part of the polysilicon pattern.

In power MOSFET 100, the gaps are provided between two perpendicular metal gate runner segments 118 (e.g., between metal gate runner segments 118-6 and 118-7) or between an end of a metal gate runner segment (e.g., metal gate runner segment 118-1) and the metal gate pad 102. Such an approach may use a small number of gaps 119, but also may have a larger impact on switching speed, as all of the unit cell transistors that are fed by a metal gate runner segment 118 that is on the far side of the gap 119 will experience the increased delay in gate signal distribution caused by the gap 119.

Pursuant to further embodiments of the present invention, a larger number of smaller gaps may be provided in the metal gate runner of a power semiconductor device. A power MOSFET 300 that takes such an approach is depicted in FIG. 5, which provides a schematic plan view of power MOSFET 300 that corresponds to the view of FIG. 3B of power MOSFET 100. Power MOSFETs 100 and 300 may be identical to each other except that power MOSFET 300 includes a larger number of gaps 319 in the metal gate runner, and the size of the gaps 319 are smaller than the size of the gaps 119 of power MOSFET 100. Because of the additional gaps 319, power MOSFET 300 includes a total of sixteen metal gate runner segments 318-1 through 318-16, as shown in FIG. 5. Since power MOSFET 300 includes twelve gaps 319 (as compared to four gaps 119 in power MOSFET 100), the amount of on-state current that will flow through the source metallization 170 above each gap 319 is reduced as compared to power MOSFET 100. As such, the size of each gap 319 may be reduced while maintaining the same on-state resistance as power MOSFET. Moreover, the unit cell transistors that are fed by metal gate runner segments 318 that are connected to the metal gate pad 102 through either one or two gaps 319 will receive the gate signal more quickly than the corresponding unit cell transistors in power MOSFET 100, since the length of one or two gaps 319 is less than the length of a single gap 119 in the metal gate runner 116 of power MOSFET 100. Thus, by providing a larger number of smaller gaps 319 in the metal gate runner it may be possible to improve the switching speed with little or no degradation in the on-state resistance of the device. Moreover, providing a larger number of gaps 319 may also advantageously further improve the uniformity of the on-state current distribution as compared to power MOSFET 100.

FIG. 6 is a schematic cross-sectional view of a gate trench power MOSFET 400 according to embodiments of the present invention. The plan views of FIGS. 3A and 3B accurately represent power MOSFET 400 as well as power MOSFET 100, and the cross-sectional view shown in FIG. 6 is taken along a vertical cut through box A of FIG. 3B.

As shown in FIG. 6, power MOSFET 400 includes a semiconductor layer structure 420. The semiconductor layer structure 420 includes a substrate 422 and a drift region 424 that may be identical to substrate 122 and a drift region 124 of power MOSFET 100. The semiconductor layer structure 420 of power MOSFET 400 further comprises a JFET region 428, a plurality of p-wells 430 and a plurality of source regions 440 which may be identical to the similarly numbered elements (i.e., elements with a reference number that is three hundred less than the reference numbers in FIG. 6) of power MOSFET 100 except that the shapes of these regions are different in power MOSFET 400.

As can be seen by comparing FIGS. 3D and 6, power MOSFET 400 primarily differs from power MOSFET 100 in that the gate dielectric layers 452 and gate electrodes 450 of power MOSFET 400 are formed within trenches 456 in the semiconductor layer structure 420 instead of being formed on a planar upper surface of a semiconductor layer structure 120 as is the case with power MOSFET 100. As a result, the channels 432 are formed in the portions of the p-wells 430 that form the sidewalls of the trenches 456. Thus, in power MOSFET 400 the channels 432 are vertical channels whereas in power MOSFET 100 the channel 132 are horizontal channels. As is further shown in FIG. 6, p-type trench shields 436 may be formed underneath each gate trench 456 and/or p-type support shields 438 may be formed in between each pair of gate trenches 456.

Power MOSFET 400 is thus very similar to power MOSFET 100, with the primary difference being that the gate electrodes 450 are formed within trenches 456 in the semiconductor layer structure 420. As such, power MOSFET 800 may look identical to power MOSFET 100 in the view of FIG. 3B. It will be appreciated that the metal gate runner designs according to embodiments of the present invention may be used in power MOSFETs having trench gate electrodes. In fact, any of the power MOSFETs discussed above with respect to FIGS. 3A-5 may have either a planar gate electrode design or a trench gate electrode design.

While the above discussion focuses on power MOSFETs that have mesh gate designs in which the gate electrodes extend in both the horizontal and vertical directions when the power MOSFET is viewed in plan view, it will be appreciated that embodiments of the present invention are not limited thereto. In particular, the techniques disclosed herein may be used in power MOSFETs having gate electrodes that only extend in the one direction. In such power MOSFETs, the metal gate runner designs may need to be modified slightly (e.g., the lengths of one or more inner or outer segments may need to be lengthened) so that every gate electrode connects to the metal gate runner, since the individual gate electrodes are not interconnected through a gate electrode mesh. It will also be appreciated that the techniques disclosed herein are equally applicable to power MOSFETs having so-called cell designs where hexagonal or other-shaped unit cells are provided.

While the above discussion focuses on n-channel MOSFETs, it will be appreciated that pursuant to further embodiments of the present invention, the polarity of each of the semiconductor layers in each device could be reversed so as to provide corresponding p-channel MOSFETs. Likewise, while the embodiments of the present invention discussed above are MOSFETs, it will be appreciated that the techniques disclosed herein may also be used to form insulated gate bipolar junction transistors (IGBTs) that include a MOSFET according to embodiments of the present invention, or other gate controlled power semiconductor devices.

Herein, embodiments of the present invention are described with respect to cross-sectional diagrams that show one or two unit cells of a power switching devices. It will be appreciated that actual implementations will typically include a much larger number of unit cells. However, it will also be appreciated that the present invention is not limited to such devices, and that the claims appended hereto also cover MOSFETs and other power switching devices that comprise, for example, a single unit cell. Moreover, while the present disclosure focuses on silicon carbide devices, it will be appreciated that embodiments of the present invention may also have applicability to devices formed using other wide band-gap semiconductors such as, for example, gallium nitride, zinc selenide or any other II-VI or III-V wide band-gap compound semiconductors.

The invention has been described above with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. It will be understood that when an element or layer is referred to as being “on”, “connected to” or “coupled to” another element or layer, it can be directly on, connected or coupled to the other element or layer, or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items. Like numbers refer to like elements throughout.

It will be understood that although the terms first and second are used herein to describe various regions, layers and/or elements, these regions, layers and/or elements should not be limited by these terms. These terms are only used to distinguish one region, layer or element from another region, layer or element. Thus, a first region, layer or element discussed below could be termed a second region, layer or element, and similarly, a second region, layer or element may be termed a first region, layer or element without departing from the scope of the present invention.

Relative terms, such as “lower” or “bottom” and “upper” or “top,” may be used herein to describe one element's relationship to another element as illustrated in the drawings. It will be understood that relative terms are intended to encompass different orientations of the device in addition to the orientation depicted in the drawings. For example, if the device in the drawings is turned over, elements described as being on the “lower” side of other elements would then be oriented on “upper” sides of the other elements. The exemplary term “lower” can, therefore, encompass both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Herein, the term “plurality” means two or more.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises,” “comprising,” “includes” and/or “including,” when used herein, specify the presence of stated features, elements, and/or components, but do not preclude the presence or addition of one or more other features, elements, components, and/or groups thereof.

Embodiments of the invention are described herein with reference to cross-sectional illustrations that are schematic illustrations. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Thus, the regions illustrated in the figures are schematic in nature and their shapes are not intended to illustrate the actual shape of a region of a device and are not intended to limit the scope of the invention.

It will be understood that the embodiments disclosed herein can be combined. Thus, features that are pictured and/or described with respect to a first embodiment may likewise be included in a second embodiment, and vice versa.

While the above embodiments are described with reference to particular figures, it is to be understood that some embodiments of the present invention may include additional and/or intervening layers, structures, or elements, and/or particular layers, structures, or elements may be deleted. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

1. A semiconductor device, comprising:
a semiconductor layer structure that comprises at least one wide bandgap semiconductor layer;
a gate pad on the semiconductor layer structure; and
a gate runner that is electrically connected to the gate pad, the gate runner comprising a polysilicon gate runner and a metal gate runner on the polysilicon gate runner opposite the semiconductor layer structure,
wherein a gap is provided in the metal gate runner above a first portion of the polysilicon gate runner, where the gap separates the metal gate runner into a first metal gate runner segment and a second metal gate runner segment or separates the first metal gate runner segment from the gate pad.

2. The semiconductor device of claim 1, wherein the gap separates the metal gate runner into the first and second metal gate runner segments, and wherein the first portion of the polysilicon gate runner electrically connects the first metal gate runner segment to the second metal gate runner segment.

3. The semiconductor device of claim 2, further comprising a source metallization on the semiconductor layer structure, wherein a portion of the source metallization extends above and vertically overlaps the gap.

4. The semiconductor device of claim 3, further comprising:
a source bond wire that is electrically connected to the source metallization and is on a first side of the gap when the semiconductor device is viewed from above; and
a unit cell transistor that is on a second side of the gap when the semiconductor device is viewed from above, the second side of the gap opposite the first side of the gap,
wherein a primary current path from the unit cell transistor to the source bond wire is through the portion of the source metallization that extends above and vertically overlaps the gap.

5-7. (canceled)

8. The semiconductor device of claim 2, wherein a first distance between the first and second metal gate runner segments across the gap is less than 10% a length of a longest side of the semiconductor layer structure.

9. (canceled)

10. The semiconductor device of claim 2, wherein the first metal gate runner segment is collinear with the second metal gate runner segment.

11. The semiconductor device of claim 2, wherein the first metal gate runner segment extends along a first longitudinal axis and the second metal gate runner segment extends along a second longitudinal axis that is perpendicular to the first longitudinal axis.

12. The semiconductor device of claim 1, wherein the first metal gate runner segment and the second metal gate runner segment are each part of an inner gate runner, and wherein the inner gate runner comprises a spine and rib configuration that comprises a spine and a plurality of ribs, wherein the gap is in between the spine and a first of the ribs.

13. (canceled)

14. The semiconductor device of claim 1, wherein the gap separates the first metal gate runner segment from the gate pad, and wherein the first portion of the polysilicon gate runner electrically connects the first metal gate runner segment to the gate pad.

15-19. (canceled)

20. A semiconductor device, comprising:
a semiconductor layer structure;
a gate pad on the semiconductor layer structure; and
a metal gate runner on the semiconductor layer structure that comprises first and second metal gate runner segments that are spaced-apart from each other by a gap, where a primary electrical connection between the second metal gate runner segment and the gate pad is through the first metal gate runner segment.

21. The semiconductor device of claim 20, further comprising a source metallization on the semiconductor layer structure that is above and vertically overlaps the gap.

22. The semiconductor device of claim 21, wherein the metal gate runner is part of a gate runner that is electrically connected to the gate pad, the gate runner further comprising a polysilicon gate runner that is in between the metal gate runner and the semiconductor layer structure, wherein a first portion of the polysilicon gate runner extends underneath the gap and electrically connects the first metal gate runner segment to the second metal gate runner segment.

23-24. (canceled)

25. The semiconductor device of claim 21, further comprising:
a source bond wire that is electrically connected to the source metallization and is on a first side of the gap when the semiconductor device is viewed from above, and
a unit cell transistor that is on a second side of the gap that is opposite the first side of the gap when the semiconductor device is viewed from above,
wherein a primary current path from the unit cell transistor to the source bond wire is through a portion of the source metallization that extends above and vertically overlaps the gap.

26. (canceled)

27. The semiconductor device of claim 21, wherein the source metallization includes a first opening when the semiconductor device is viewed from above and the first metal gate runner segment is within the first opening in the source metallization and surrounded by the source metallization.

28-30. (canceled)

31. The semiconductor device of claim 21, wherein the gap is a first gap, and wherein the metal gate runner is separated from the gate pad by a second gap, and a polysilicon gate runner is provided beneath the second gap, and the source metallization extends above and vertically overlaps the second gap.

32-39. (canceled)

40. A semiconductor device, comprising:
a semiconductor layer structure;
a gate pad on the semiconductor layer structure;
a source metallization on the semiconductor layer structure; and
a metal gate runner on the semiconductor layer structure that comprises at least first and second metal gate runner segments,
wherein the source metallization comprises a first opening when the semiconductor device is viewed from above, and the first metal gate runner segment is within the opening and the second metal gate runner segment is outside the opening when the semiconductor device is viewed from above.

41. The semiconductor device of claim 40, wherein the metal gate runner is part of a gate runner that is electrically connected to the gate pad, the gate runner further comprising a polysilicon gate runner that is in between the metal gate runner and the semiconductor layer structure.

42. The semiconductor device of claim 41, wherein the first and second metal gate runner segments are separated from each other by a gap, and a first portion of the polysilicon gate runner extends underneath the gap.

43. The semiconductor device of claim 42, wherein the first portion of the polysilicon gate runner electrically connects the first metal gate runner segment to the second metal gate runner segment.

44. The semiconductor device of claim 42, further comprising:
a source bond wire that is electrically connected to the source metallization and is on a first side of the gap when the semiconductor device is viewed from above, and
a unit cell transistor that is on a second side of the gap that is opposite the first side of the gap,
wherein a primary current path from the unit cell transistor to the source bond wire is through a portion of the source metallization that extends above and vertically overlaps the gap.

45-46. (canceled)

47. The semiconductor device of claim 42, wherein the gap is a first gap, and wherein the metal gate runner is separated from the gate pad by a second gap, and a polysilicon gate runner is provided beneath the second gap, and the source metallization extends above the second gap.

48. (canceled)

49. The semiconductor device of claim 41, wherein the first metal gate runner segment and the gate pad are separated from each other by a gap, and a first portion of the polysilicon gate runner extends underneath the gap.

50-74. (canceled)
